(19) United States
(12) Patent Application Publication
(10) Pub. No.: US 2002/0124385 A1
(43) Pub. Date: Sep. 12, 2002

(54) Micro-electro-mechanical high frequency switch and method for manufacturing the same

(75) Inventors: Shu-Hui Tsai, Hsin-Chu City (CN); Cheng-Kuo Lee, Hsin-Chu City (CN); Chung-Hsien Lin, Chia-I City (CN); Chun-Hsien Lee, Taipei (CN); Fan Kuan Jen, Tainan (CN)

Correspondence Address: BRUCE H. TROXELL, 5205 LEESBURG PIKE, SUITE 1404, FALLS CHURCH, VA, 22041, US

(73) Assignee: ASIA PACIFIC MICROSYSTEM, INC.

(21) Appl. No.: 10/028,822

(22) Filed: Dec. 28, 2001

(30) Foreign Application Priority Data
Dec. 29, 2000 (TW) 089128261

(51) Int. Cl. H01H 11/04; H05K 3/20

(52) U.S. Cl. 29/622; 29/831

(57) ABSTRACT

A micro-electro-mechanical high frequency switch and method for manufacturing the high frequency switch, comprising the steps of: providing a substrate; forming a metal transmission line and a driving electrode on the substrate; forming a dielectric layer on said metal transmission line and said driving electrode; forming a micro-electro-mechanical switch; forming driving electrodes on and beneath the micro-electro-mechanical switch; such that the driving voltage of high frequency switch is reduced, the insertion loss is lowered, the isolation is high, and the functions of high frequency switch is improved.

### BACKGROUND OF THE INVENTION

The present invention relates to a micro-electro-mechanical high frequency switch and method for manufacturing the same. Especially to those can be integrated with coplanar waveguide transmission line, integrated with micro-electro-mechanical package, increasing the actuating voltage, improving the insertion loss and isolation.

### DESCRIPTION OF THE PRIOR ART

As the development of information, high frequency techniques or components are applied to many purposes. Weather satellites, RF (high frequency) communication and weaponry systems, and wireless communication for civil use, etc., each needs various RF components. The RF switch is a basic and very important component of the high frequency components. The scope of applying this includes the Tx/Rx switch of the receiving end of an antenna, the switching of the multi-band or diversity antenna, the switching filter module or radio frequency module, and the multiplexing selectors of power/gain/loss/delay etc. There are various selections for the standards of the RF switch, according to the applied frequency band, the quantity of power, and the functions. In generally, except for being integratablized and being integrated in the MMIC (microwave monolithic IC) for portable products, and in principle of the loss tolerance of the whole multiplexing selector that does not over 2 dB, the main switching components should be low insertion loss, high isolation in the range of the using frequency band. The more prosperous the communication business is, the more complicated the corresponding functions of transceiver modules are, and the more important the switching components are. Therefore, the standards of the switching component are required more sternly. Presently, there are approximately two kinds of main products of the RF switch on the market: one is gallium arsenide metal-semiconductor field effect transistor (GaAs MESFET), another one is GaAs PIN diode. To operate the GaAs MESFET, by operating the gate voltage (negative voltage operating) to control the channel of both ends of the source and drain, thus it can be integrated with the integrated microwave IC (MMIC) to reduce the size and cost of the chip. However, since the breakdown voltage between the source and drain is being restricted, it is not suitable for operating with higher power. In order to achieve a good operation with high power, the way is connecting with several GaAs MESFET in series (M. Shifrin at.al, 1989), or, applying a capacitor between the drain and the source (Hitachi Ltd., 1999). But, the size of the chip is comparatively increased and, as the impedance mismatching and the inserting loss increased when several GaAs MESFET are series connected, the RF operation is restricted. The current-voltage properties of the PIN diode enable it to be a good RF switching component, and the properties of high breakdown voltage are satisfied with various power requirement. However, as applying the power source bias of the PIN diode, it is required the RF choke and capacitors that are selected appropriately. Therefore, since the module becomes more complicated so that it is not easy to make the PIN diode integrated with other MMIC, it can not be operated in linearity, and the cost of the component unit is pushed higher. Furthermore, there is also a tendency that the products are being designed power saving in the future. For example, a conventional phase-array antenna for radar communicating containing thousands of antenna elements, of which each antenna element requires several switches. Nevertheless, these switches bring on high cost, high power consuming, and their quality are not good enough. It is because there is insertion loss generated by the PIN diode while applying higher power and higher frequency. But comparing with the GaAs MESFET, the PIN diode has a low integrated extent and is high power consuming, and the FET has higher insertion loss. Therefore, as described above, with the applications requiring switching array and the applications for RF range such as X-band (centered at 10 GHz) and Ka-band (centered at 35 GHz), the micro-electro-mechanical switch can provide good properties of RF switches, and has the advantages of low power consuming, and high integrated process simultaneously.

Presently, the disadvantages of the solid-state electronic type RF switch are that the insertion loss during “on” state is too large, and bad isolation occurred during “off” state. The micro-electro-mechanical switch can solve the above-mentioned disadvantages. The micro-electro-mechanical switch is not operated at the RF mode directly, and it enables itself to be adjusted or switched by its good micro-electro-mechanical actuators. The advantage of the RF components using micro-electro-mechanical techniques is, it is well isolated between the electro-mechanical and RF, that is, the signals between the RF networks would not be a short circuit or coupled to the actuating circuit. Another advantage is low power consuming, thus a linear switch is achieved because of low interference, and it can be integrated. It not only shows its excellent insertion loss and isolation and its excellent linear operation by using the micro-electro-mechanical techniques for manufacturing the switches. Moreover, the switch components with various frequencies, power and structures, which can be designed by adjustment of designing and the manufacturing process, can be collocated with modules with various standards. Wherein, the power consumed is so low while operating the static electrical enabled type switch at the on/off state, so it is very suitable for the relative components of portable, mobile products.

Presently, the electrostatic actuated type RF micro-electro-mechanical switch includes series-connecting type switch and shunt-connecting type switch. In the scheme of micro-strip transmission line can the series-connecting type switch be used; while in the schemer of co-planar waveguide transmission line, both the series-connecting type switch and the shunt-connecting type switch can be applied. Presently, although the insertion loss of the series-connecting type at LF (low frequency) range is quite low, the insertion loss at RF range is quite high, and the isolation is quite well whenever at LF or RF ranges. The isolation of the shunt-connecting type switch at LF range is worse, the isolation at RF range is better, and the insertion loss is quite low whenever at LF or RF range. Therefore, in the conventional technology, if there is no improvement about the functions of the switch while applying it, the series-connecting type switch is more suitable for LF range operation, and the shunt-connecting type switch is more suitable for RF operation.

FIGS. 1a through 1c are perspective views of the conventional electrostatic actuated type RF micro-electro-mechanical switch. As shown in FIG. 1a, the micro-electro-mechanical switch can be formed on the substrate 12, wherein, it consists of a supporting portion 13, a cantilever beam 14 connecting with supporting portion 13 used as a switching actuator, a driving electrode 15 certainly located under the cantilever beam 14 for providing the cantilever beam 14 with electrostatic actuating. According to the formula, the formula of the driving voltage of the switch is:

$${V}_{p} = \sqrt{\frac{8 {KG}^{3}}{27 ϵ A}} \qquad ( 1 )$$

wherein K is the entirety spring constant of the cantilever beam 14, G is the distance between the cantilever beam 14 and the driving electrode 15, ε is the dielectric constant of the filler between the cantilever beam 14 and the driving electrode 15, A is the area of the driving electrode 15. It is known from the above formula that, in order to reduced the driving voltage of the switch, by lowering the entirety spring constant K, reducing the distance G between the cantilever beam 14 and the driving electrode 15, increasing the area A of the driving electrode 15, or increasing the dielectric constant ε of the filler between the cantilever beam 14 and the driving electrode 15. However, in the conventional electrostatic actuated type RF micro-electro-mechanical switch, the distance G between the cantilever beam 14 and the driving electrode 15 should not be too short to avoid lowering the isolation of the RF micro-electro-mechanical switch at “off” state, and generally, it should be 1.5 μm to 2 μm. In this structure, the filler between the cantilever beam 14 and the driving electrode 15 is air or vacuum (dielectric constant ε˜1). Presently, changeable parameters are the area A of the driving electrode 15 and the entirety spring constant K of the cantilever beam 14. According to the formula (2), the bending spring constant K of the cantilever beam 14 is:

$${K}_{B} = \frac{3 EI}{{L}^{3}} • I = \frac{{BH}^{3}}{12} \qquad ( 2 )$$

wherein, E is the Young's modulus of the cantilever beam 14, I is moment of inertia of the cantilever beam 14, B, H, and L is the width, depth, and length of the cantilever beam 14. A lower elasticity constant K can be achieve by increasing the equivalent length, decreasing the depth and the width of the cantilever beam 14, or using a material with lower Young's modulus E for the structure body of the cantilever beam 14. But, the occupied area of the RF switch formed by the cantilever beam 14 with lower spring constant K is being larger, and the structure is quite unstable. Moreover, it may not recover during the restoring state, and thus lowering the switching speed. There is another disadvantage of the conventional electrostatic actuated type RF micro-electro-mechanical switch: the electrode 15 (force applied point) is located between the supporting point 13 and the switch contact point 16, and it is a laborious but time saving lever. But, if the electrode 15 (force applied point) is moved out of the switch contact point 16, it is a time wasting but labor saving lever. In the structure of the latter, while the cantilever beam 14 is contacting with the driving electrode 15, the contact point 16 cannot contact with the contact point 17 closely, thus the properties of the RF switch is lowered.

There is another disadvantages of the conventional electrostatic actuated type RF micro-electro-mechanical switch: while it is applied to the switch of the coplanar waveguide transmission line, the layout of the cantilever beam 14 and the driving electrode 15 are rather restricted. FIG. 1b shows the layout of the coplanar waveguide transmission RF switch. Referring to FIG. 1b, wherein 17a, 17c are the ground plane of the coplanar waveguide transmission line, and 17b is the signal line of the coplanar waveguide transmission line. Since the ground plane of the coplanar waveguide transmission line 17a and 17c exist, they actuate the electrode 15 to be approached to the supporting point 13, and if the force applied arm is fixed, the supporting point 13 must be moved outward, as a result, the whole area of the chip is increased. On the other hand, as shown in FIG. 1c, while the switch is switched down, the switch contacting points 16a, 16b, and 16c are not at the same level, thus the switch contacting points 16a, 16b, and 16c can not contact with the switch contacting points 17a, 17b and 17c closely, and thus the isolation or the insertion loss is being worse.

FIG. 2 shows another type of the conventional electrostatic actuated type RF micro-electro-mechanical switch. That is, shunt-connecting RF micro-electro-mechanical switch. As shown in FIG. 2, the micro-electro-mechanical switch can be formed on the substrate 22, wherein it includes two side-supporting portions 23 applied as a switching actuator located certainly below the thin film 24. There is a driving electrode 25 interposed under the transmission line for providing electrostatic force to the thin film 24.

As shown in FIG. 2, the advantage of the shunt-connecting RF micro-electro-mechanical switch is that the structure is more stable, thus it is suitable for the layout of coplanar waveguide transmission line, and the occupied volume is small. But the isolation of the shunt-connecting switch at LF range is quite bad, and the driving electrode 25 is formed before the transmission line 27b deposited, thus a non-continuous step is formed by the transmission line 27b formed afterward and the properties are affected. On the other hand, the driving voltage of this type of RF micro-electro-mechanical switch is quite high, for example, the shunt-connecting RF micro-electro-mechanical switch developed by the Raytheon Company (the thesis “Performance of low-loss RF MEMS capacitive switches” disclose by Goldsmith on August 1998 at IEEE Microwave and Guided Wave Letters, which the driving voltage is between 30˜50 volts.

It is known from above, the RF micro-electro-mechanical switch can be classified by series-connecting switch and shunt-connecting switch. The series-connecting micro-electro-mechanical switch is suitable for LF fields, and the shunt-connecting micro-electro-mechanical switch is suitable for RF fields. However, the switching speed of the series-connecting micro-electro-mechanical switch is too low, and the driving voltage of the shunt-connecting micro-electro-mechanical switch is too high. There is required for considering choosing between the broadband, high speed, driving voltage and the circuit layout.

### SUMMARY OF THE INVENTION

The object of the present invention is to solve the above-mentioned disadvantages in the conventional techniques.

Therefore, it is an object of the present invention to provide a micro-electro-mechanical RF switch combining with series-connecting type and shunt-connecting type and the method for manufacturing the same, which enables itself to be integrated with the layout of coplanar waveguide transmission lines easily, and enables the layout of the driving electrode to be optimized, thus, it enables the driving voltage of the RF switch to be lowered, and provides a micro-electro-mechanical RF switch with low insertion loss and high isolation, and, the properties of the RF switch is improved.

Another object of the present invention is to provide a improved shunt-connecting micro-electro-mechanical RF switch and method for manufacturing the same, which enables the conventional shunt-connecting micro-electro-mechanical RF switch, of which the driving voltage to be lowered, and provides a micro-electro-mechanical RF switch with low insertion loss and high isolation, and, the properties of the RF switch is improved.

Another object of the present invention is to provide a micro-electro-mechanical RF switch integrated with micro-electro-mechanical packaging and method for manufacturing the same without complicating the process, it enables the driving voltage to be lowered, and provides a micro-electro-mechanical RF switch with low insertion loss and high isolation, and, the properties of the RF switch is improved.

Another object of the present invention is to provide another micro-electro-mechanical RF switch integrated with micro-electro-mechanical packaging and method for manufacturing the same without complicating the process, it enables the driving voltage to be lowered, and provides a micro-electro-mechanical RF switch with low insertion loss and high isolation, and, the properties of the RF switch is improved.

In order to achieve the above-mentioned objects, according to the method of manufacturing the circuit board of the present invention, it includes the steps as below: forming a micro-electro-mechanical switch on the substrate, it comprises supporting portions; a cantilever beam, of which one end is connected with the supporting portion, used as a switch actuator; a driving electrode beneath the cantilever beam for providing static electricity to actuate the cantilever beam.

In order to achieve the above-mentioned objects, according to the method of manufacturing the circuit board of the present invention, it further comprises the steps as below: the micro-electro-mechanical switch can be formed on the substrate, wherein including the supporting portion; a cantilever beam, of which one end is connected with the supporting portion, used as a switch actuator; a driving electrode beneath the cantilever beam for providing static electricity to enable the cantilever beam; in addition, an upper driving electrode located certainly on the switch for providing static electricity to enable the cantilever beam and lower the driving voltage thereof.

In order to achieve the above-mentioned objects, according to the method of manufacturing the circuit board of the present invention, it further comprises the steps as below: the micro-electro-mechanical switch can be formed on the substrate, wherein including the supporting portion; a cantilever beam, of which one end is connected with the supporting portion, used as a switch actuator; a driving electrode beneath the cantilever beam for providing static electricity to enable the cantilever beam; in addition, an upper driving electrode located certainly on the switch for providing static electricity to enable the cantilever beam and lower the driving voltage thereof.

The above objectives and advantages will become more apparent with explanation of the accompanying drawings.

### BRIEF DESCRIPTION OF THE DRAWINGS

FIGS. 1a through 1c are perspective views of the conventional series-connecting type and shunt-connecting type electrostatic actuated type RF micro-electro-mechanical switch.

FIG. 2 is a perspective view of the conventional shunt-connecting type electrostatic actuated type RF micro-electro-mechanical switch.

FIGS. 3a and 3b are perspective views of the electrostatic actuated type RF micro-electro-mechanical switch according to the first embodiment of the present invention.

FIG. 4 is a perspective view of the electrostatic actuated type RF micro-electro-mechanical switch according to the second embodiment of the present invention.

FIG. 5 is a perspective view of the electrostatic actuated type RF micro-electro-mechanical switch according to the third embodiment of the present invention.

FIGS. 6a through 6c are views of the electrostatic actuated type RF micro-electro-mechanical switch, showing the relationship between the electrostatic repelling and attracting forces and the position of the switch.

### DETAILED DESCRIPTION OF THE PREFERRED EMBODIMENT

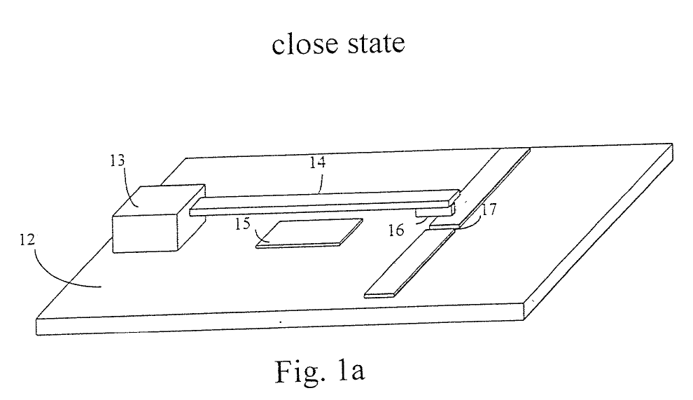

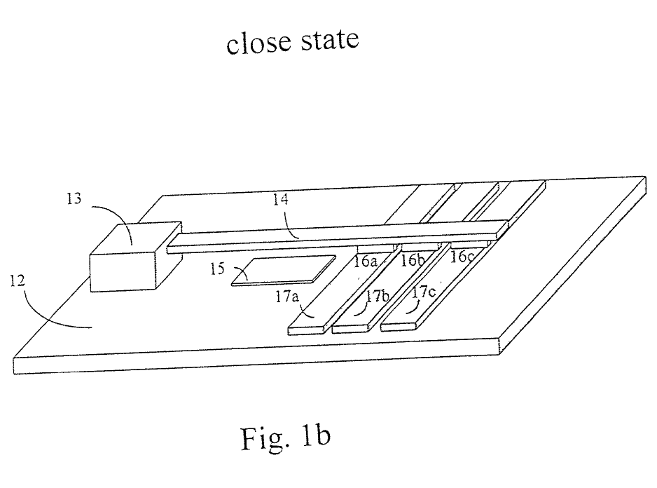

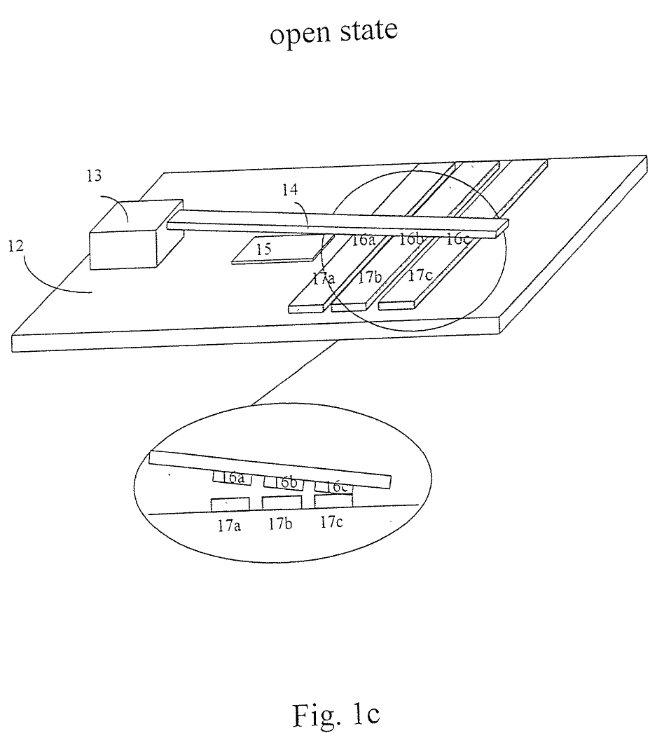

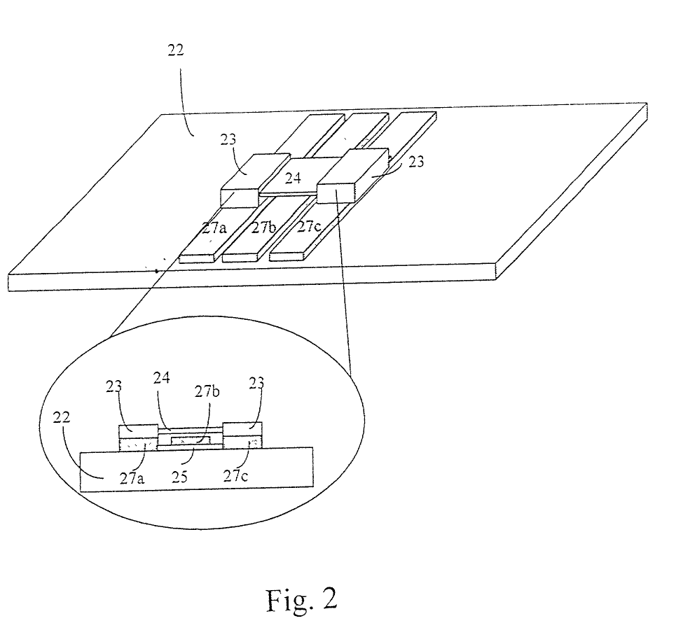

The conventional series-connecting type and shunt-connecting electrostatic actuated type RF (high frequency) micro-electro-mechanical switch in FIGS. 1a, 1b, 1c, and 2 has described as above, it is not repeated here.

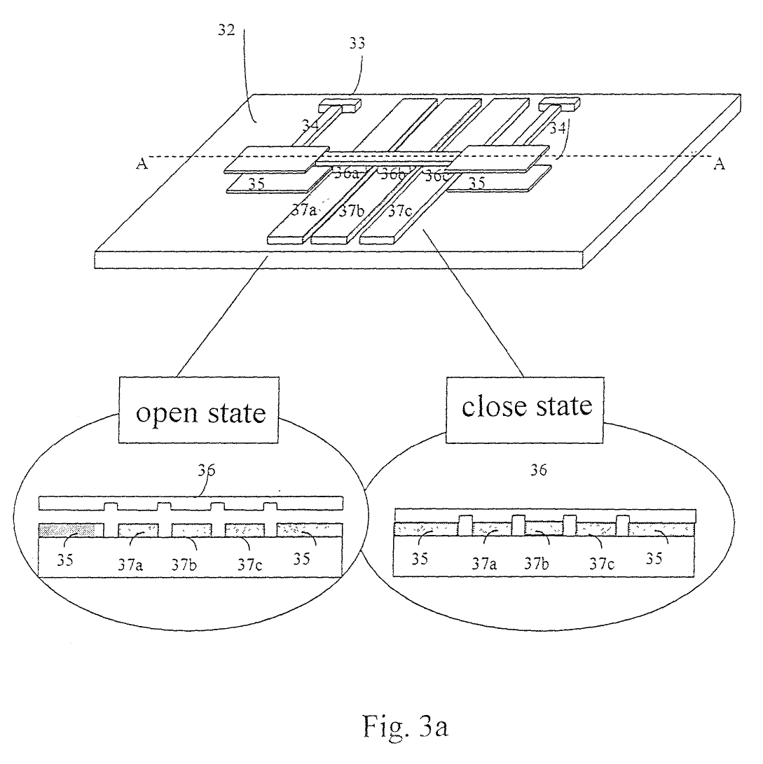

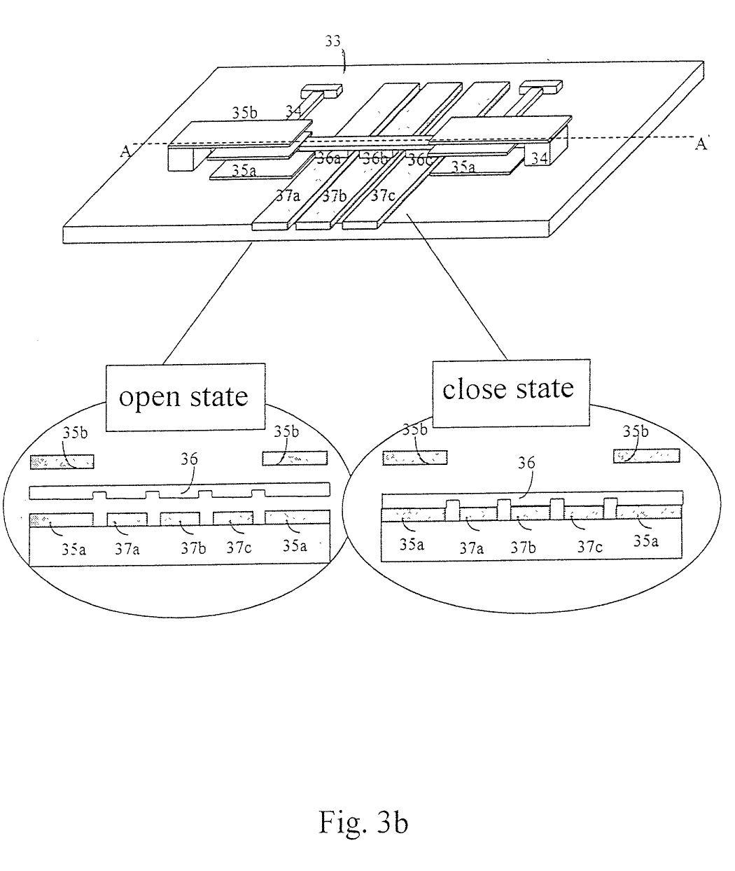

FIGS. 3a and 3b are perspective views of the electrostatic actuated type RF micro-electro-mechanical switch according to the first embodiment of the present invention. The whole structure has the advantages combining with the advantages of the series-connection and shunt-connection, thus enables a more stable structure can be maintained, and achieves low driving voltage operation. As shown in FIG. 3a, the micro-electro-mechanical switch can be formed on a substrate 32, wherein it comprises supporting portions 33; it also comprises a cantilever beam 34 used as a switching actuator, beneath the cantilever beam 34, there is a driving electrode 35 for providing static electricity to actuate the cantilever beam 34. In this structure, since the driving electrodes 35 is located at the two sides of the coplanar waveguide transmission line, in order to lower the driving voltage of the switch, the entire spring constant K of the cantilever beam 34 is not lowered and the distance G between the cantilever beam 34 and the driving electrodes 35 is not shorten, but the area A of the driving electrodes 35 is increased to lower the voltage for driving the switch.

In addition, as shown in FIG. 3b, another structure of this embodiment can be stabilized by applying upper and lower bi-electrode on the driving electrode 35. According to FIG. 3b, the micro-electro-mechanical switch can be formed on a substrate 32, wherein it comprises supporting portions 33, two fixed ends respectively across both ends of the coplanar waveguide transmission line and connecting with supporting portions 33. It also comprises a cantilever beam 34 used as a switching actuator; there is a driving electrode 35a beneath the cantilever beam 34 for providing static electricity to enable the cantilever beam 34; there is a driving electrode 35b on the cantilever beam 34 for providing recovering static electricity to actuate the switch to be maintained stable.

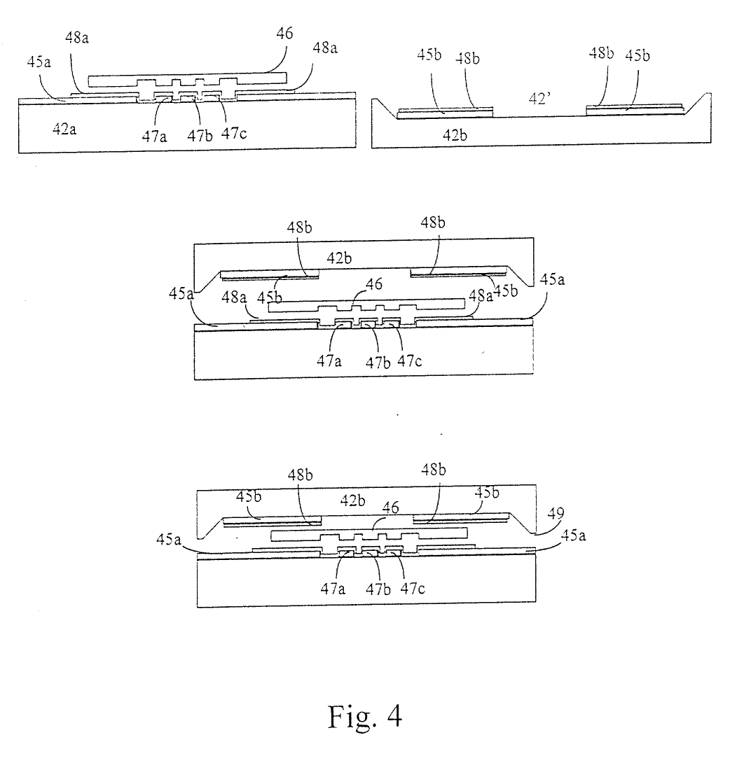

FIG. 4 is a perspective view of the electrostatic actuated type RF micro-electro-mechanical switch according to the second embodiment of the present invention. As shown in FIG. 4, it shows the embodiment, of which the structure is being proceeded with the micro-electro-mechanical packaging on the driving electrode 45, an upper electrode 45b is provided as the upper electrode 45a in the first embodiment, thus the processing complication is reduced. As shown in FIG. 4, the micro-electro-mechanical switch can be formed on the substrate 42a, wherein it comprises supporting portions 43, two fixed ends respectively across both ends of the coplanar waveguide transmission line and connecting with the supporting portions 43. It also comprises a cantilever beam 44 used as a switching actuator; there is a driving electrode 45a beneath the cantilever beam 44 for providing static electricity to actuate the cantilever beam 44. It also comprises a deep trough 42′ formed on another substrate 42b; an upper driving electrode 45b is formed by forming a metal layer on the deep trough 42′. Then, by the method of flip-chip or wafer level chip scale packaging, the substrate 42b including the deep trough 42′ and the upper driving electrode 45b is connected with the substrate 42a having the lower electrode 45a, the supporting portions 43, and the cantilever beam 44. The advantage of this embodiment is, not as the second embodiment that it is required for two sacrificial layers, that the processing complication is reduced greatly.

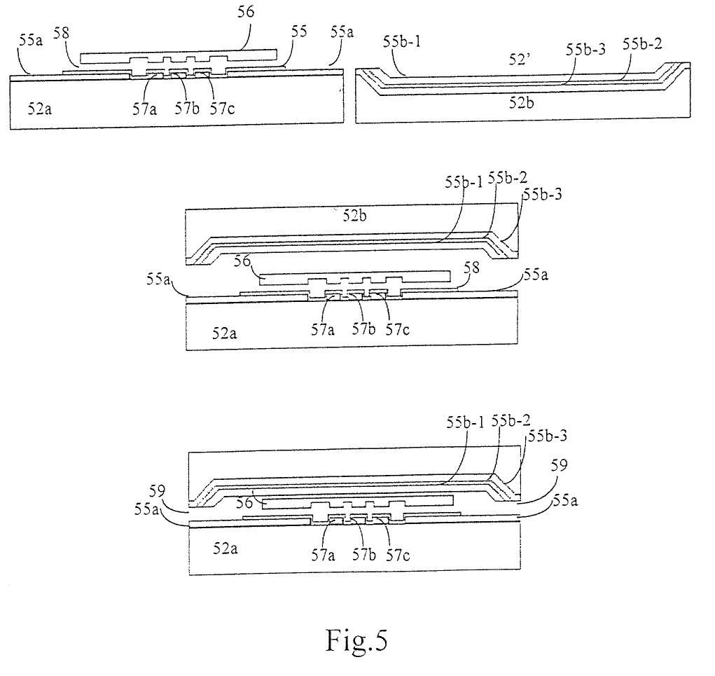

FIG. 5 is a perspective view of the electrostatic actuated type RF micro-electro-mechanical switch according to the third embodiment of the present invention. The actuating principle of the micro-electro-mechanical RF switch is by combining mainly with the electrostatic repelling and attracting force.

As shown in FIG. 5, it shows the embodiment, of which the structure is being proceeded with upper and lower bi-electrodes, wherein the micro-electro-mechanical packaging provides an upper electrode 55b used as the upper electrode 55b in the first embodiment for lowering the processing complication; the upper electrode have a structure of repelling electrode including the first metal layer 55b-1, the first insulating layer 55b-2, and the second metal layer 55b-3.

As shown in FIG. 5, the micro-electro-mechanical switch can be formed on the substrate 52a, wherein it comprises supporting portions 53, two fixed ends respectively across both ends of the coplanar waveguide transmission line and connecting with the supporting portions 53. It also comprises a cantilever beam 54 used as a switching actuator; there is a driving electrode 55a beneath the cantilever beam 44 for providing static electricity to actuate the cantilever beam 54. It also comprises a deep trough 52′ formed on another substrate 52b; the first metal layer 55b-1, the first insulating layer 55b-2, and the second metal layer 55b-3 is formed by forming a metal layer on the deep trough 52′, thus the upper driving repelling electrode 55b is formed. Then, by the method of flip-chip or wafer level chip scale packaging, Then the substrate 52b including the deep trough 52′ and the upper driving electrode 55b is connected with the substrate 52a having the lower electrode 55a, the supporting portions 53, and the cantilever beam 54.

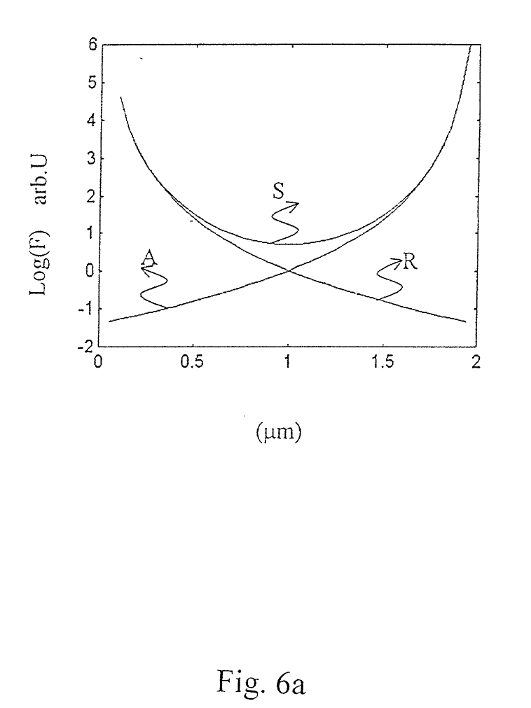

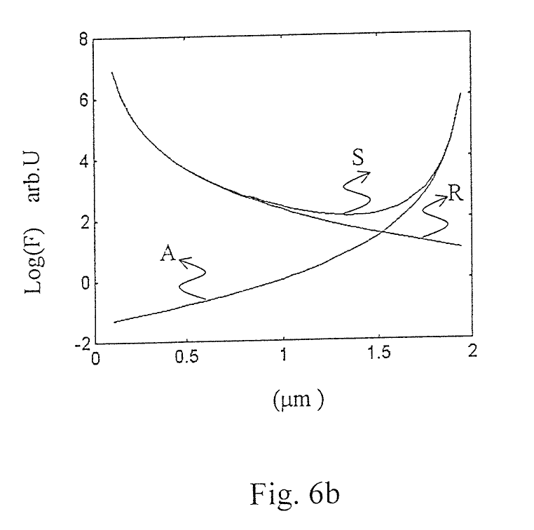

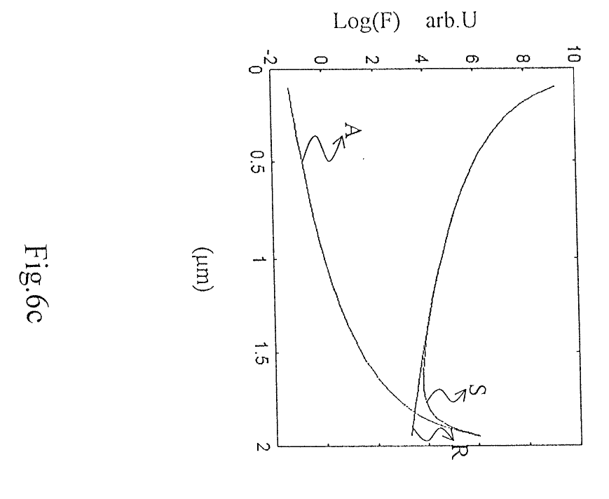

The advantages of the above embodiment is: first, it is not as the second embodiment that two sacrificial layers are required, that the processing complication is reduced greatly; another, according to the analysis from FIG. 6a, 6b, 6c showing the action forces, by means of the upper and lower electrodes for combining the electrostatic repelling and attracting force as an actuating principle of the micro-electro-mechanical RF switch, the electrostatic force for driving the switch can be reduced greatly.

As shown in FIG. 6a, the curve labeled as R indicates the relationship between the repelling force and the distance of the upper electrode; the curve labeled as A indicates the relationship between the repelling force and the distance of the lower electrode; the curve labeled as S indicates relationship between the combined force of electrostatic repelling and attracting force and the distance of the upper and lower electrodes.

According to the curve of label A, a conventional electrostatic attracting force is provided for action force, since it is the farthest at the starting position A1, it is known from the formula F=Q₁Q₂/r² of electrostatic force that the action force between thereof is very little, so it requires greater driving voltage for driving the cantilever beam 54 to the switch contacting point 57. According to the curve of label R, the acting force provided by electrostatic repelling force, since it is the nearest at the starting position R1, it is known from the formula F=Q₁Q₂/r² of electrostatic force that the action force between thereof is very great, but as the cantilever beam 54 is closed to the switch contacting point 57, the electrostatic action force is gradually getting less, and so it is also required a great driving voltage to make the cantilever beam 54 to be contacted to the switch contacting point 57 completely.

If the electrostatic repelling force is combined by the upper and lower electrodes, shown as the curve of label S, at the beginning when the cantilever beam 54 is closed to the switch contacting point 57, the greater repelling force generated by the upper electrode can be used as the main force, and as the cantilever beam 54 is moved to the middle point between the upper electrode and the switch contacting point 57, and the attracting force of the lower electrode is gradually getting greater, thus the electrostatic force of the whole curve S is much greater than a single electrostatic attracting or repelling force, therefore, the electrostatic force for driving the switch can be reduced greatly.

As shown in FIG. 6b, the curve labeled as R indicates the relationship between the repelling force and the distance of the upper electrode; the curve labeled as A indicates the relationship between the repelling force and the distance of the lower electrode; the curve labeled as S indicates relationship between the combined force of electrostatic repelling and attracting force and the distance of the upper and lower electrodes.

As the repelling force provided by the upper electrode is greater, the repelling force served as the main force is lasted to the position the cantilever beam 54 moved to that under the middle point between the upper electrode and the switch contacting point 57, and the attracting force of the lower electrode becomes the main acting force gradually; similarly, the electrostatic force of the whole curve S is much greater than a single electrostatic attracting force or electrostatic repelling force, therefore, the electrostatic force for driving the switch can be reduced greatly:

As shown in FIG. 6c, the curve labeled as R indicates the relationship between the repelling force and the distance of the upper electrode; the curve labeled as A indicates the relationship between the repelling force and the distance of the lower electrode; the curve labeled as S indicates relationship between the combined electrostatic repelling and attracting force and the distance of the upper and lower electrodes.

As the repelling force provided by the upper electrode is much greater than the attracting force, it depended on the repelling force that the whole cantilever beam 54 is moved to the switch contacting point 57, and compared with the conventional electrostatic attracting force, the electrostatic force for driving the switch can be reduced greatly.

It is known from the above description that although the present invention has been described using specified embodiment, the examples are meant to be illustrative and not restrictive. It is clear that many other variations would be possible without departing from the basic approach, demonstrated in the present invention.

What is claimed is:

1. A method for manufacturing an electrostatic actuated type high frequency micro-electro-mechanical switch, comprising the steps of:
providing a substrate;
forming a metal transmission line and a driving electrode on said substrate;
forming a dielectric layer on said metal transmission line and said driving electrode; and
forming a micro-electro-mechanical switch on said dielectric layer.

2. A method for manufacturing an electrostatic actuated type high frequency micro-electro-mechanical switch as claimed in claim 1, wherein said micro-electro-mechanical switch includes: supporting portions, respectively across the two ends of coplanar transmission line and connect to the two fixed ends of said support portion.

3. A method for manufacturing an electrostatic actuated type high frequency micro-electro-mechanical switch as claimed in claim 1, wherein the micro-electro-mechanical switch further comprises a cantilever beam, beneath the cantilever beam, there is a driving electrode for providing static electricity to actuate the cantilever beam.

4. A method for manufacturing an electrostatic actuated type high frequency micro-electro-mechanical switch as claimed in claim 2, wherein the micro-electro-mechanical switch further comprises a cantilever beam, beneath the cantilever beam, there is a driving electrode for providing static electricity to actuate the cantilever beam.

5. A method for manufacturing an electrostatic actuated type high frequency micro-electro-mechanical switch as claimed in claim 3, wherein said driving electrodes are formed at two ends of said coplanar transmission line, so as to avoid interfering the high frequency signal.

6. A method for manufacturing an electrostatic actuated type high frequency micro-electro-mechanical switch as claimed in claim 4, wherein said driving electrodes are formed at two ends of said coplanar transmission line, so as to avoid interfering the high frequency signal.

7. A method for manufacturing an electrostatic actuated type high frequency micro-electro-mechanical switch, comprising the steps of:
proving a substrate;
forming a metal transmission line and a driving electrode on said substrate;
forming a dielectric layer on said meal transmission line and said driving electrode;
forming a micro-electro-mechanical switch on said dielectric layer; and
forming driving electrodes on and under said micro-electro-mechanical switch.

8. A method for manufacturing an electrostatic actuated type high frequency micro-electro-mechanical switch as claimed in claim 7, wherein said micro-electro-mechanical switch includes: supporting portions, respectively across two ends of coplanar transmission line and connect to the two fixed ends of said support portion.

9. A method for manufacturing an electrostatic actuated type high frequency micro-electro-mechanical switch as claimed in claim 7, wherein the micro-electro-mechanical switch further comprises a cantilever beam, beneath the cantilever beam, there is a driving electrode for providing static electricity to actuate the cantilever beam.

10. A method for manufacturing an electrostatic actuated type high frequency micro-electro-mechanical switch as claimed in claim 8, wherein the micro-electro-mechanical switch further comprises a cantilever beam, beneath the cantilever beam, there is a driving electrode for providing static electricity to actuate the cantilever beam.

11. A method for manufacturing an electrostatic actuated type high frequency micro-electro-mechanical switch as claimed in claim 9, wherein the micro-electro-mechanical switch further comprises a cantilever beam for switch actuating means, above the cantilever beam, there is a driving electrode for providing static electricity to recover the cantilever beam.

12. A method for manufacturing an electrostatic actuated type high frequency micro-electro-mechanical switch as claimed in claim 10, wherein the micro-electro-mechanical switch further comprises a cantilever beam for switch actuating means, above the cantilever beam, there is a driving electrode for providing static electricity to recover the cantilever beam.

13. A method for manufacturing an electrostatic actuated type high frequency micro-electro-mechanical switch as claimed in claim 9, wherein said driving electrode is formed at two ends of said coplanar transmission line, so as to avoid interfering the high frequency signal.

14. A method for manufacturing an electrostatic actuated type high frequency micro-electro-mechanical switch as claimed in claim 10, wherein said driving electrode is formed at two ends of said coplanar transmission line, so as to avoid interfering the high frequency signal.

15. A method for manufacturing an electrostatic actuated type high frequency micro-electro-mechanical switch as claimed in claim 13, wherein said the driving electrode above the cantilever beam can be formed by using micro-electro-mechanical packaging.

16. A method for manufacturing an electrostatic actuated type high frequency micro-electro-mechanical switch as claimed in claim 14, wherein said the driving electrode above the cantilever beam can be formed by using micro-electro-mechanical packaging.

17. A method for manufacturing an electrostatic actuated type high frequency micro-electro-mechanical switch as claimed in claim 15, wherein the upper driving electrode manufactured by micro-electro-mechanical packaging includes a substrate on which a deep trough is formed, and a metal layer is formed onto the deep trough to form the upper driving electrode, then the upper driving electrode is integrated onto the micro-electro-mechanical switch by flip-chip method or wafer level chip scale packaging.

18. A method for manufacturing an electrostatic actuated type high frequency micro-electro-mechanical switch as claimed in claim 16, wherein the upper driving electrode manufactured by micro-electro-mechanical packaging includes a substrate on which a deep trough is formed, and a metal layer is plated onto the deep trough to form the upper driving electrode, then the upper driving electrode is integrated onto the micro-electro-mechanical switch by flip-chip method or wafer level chip scale packaging.

19. A method for manufacturing an electrostatic actuated type high frequency micro-electro-mechanical switch as claimed in claim 11, wherein said driving electrode is formed at two ends of said coplanar transmission line, so as to avoid interfering the high frequency signal.

20. A method for manufacturing an electrostatic actuated type high frequency micro-electro-mechanical switch as claimed in claim 12, wherein said driving electrode is formed at two ends of said coplanar transmission line, so as to avoid interfering the high frequency signal.

21. A method for manufacturing an electrostatic actuated type high frequency micro-electro-mechanical switch as claimed in claim 11, wherein the upper driving electrode can provide repelling force to enable the cantilever beam.

22. A method for manufacturing an electrostatic actuated type high frequency micro-electro-mechanical switch as claimed in claim 12, wherein the upper driving electrode can provide repelling force to actuate the cantilever beam.

23. A method for manufacturing an electrostatic actuated type high frequency micro-electro-mechanical switch as claimed in claim 21, wherein the upper driving electrode formed by micro-electro-mechanical packaging comprises a substrate, a deep trough formed on the substrate, a first metal layer, a first insulating layer and a second metal layer.

24. A method for manufacturing an electrostatic actuated type high frequency micro-electro-mechanical switch as claimed in claim 22, wherein the upper driving electrode formed by micro-electro-mechanical packaging comprises a substrate, a deep trough formed on the substrate, a first metal layer, a first insulating layer and a second metal layer.

25. A method for manufacturing an electrostatic actuated type high frequency micro-electro-mechanical switch as claimed in claim 23, wherein the upper driving electrode manufactured by micro-electro-mechanical packaging includes a substrate on which a deep trough is formed, and a metal layer is plated onto the deep trough to form the upper driving electrode, then the upper driving electrode is integrated onto the micro-electro-mechanical switch by flip-chip method or wafer level chip scale packaging.

26. A method for manufacturing an electrostatic actuated type high frequency micro-electro-mechanical switch as claimed in claim 24, the upper driving electrode manufactured by micro-electro-mechanical packaging includes a substrate on which a deep trough is formed, and a metal layer is plated onto the deep trough to form the upper driving electrode, then the upper driving electrode is integrated onto the micro-electro-mechanical switch by flip-chip method or wafer level chip scale packaging.
